(19) United States
(12) Patent Application Publication
(10) Pub. No.: US 2011/0127508 A1
(43) Pub. Date: Jun. 2, 2011

(54) ORGANIC ELECTRONIC DEVICE AND METHOD OF MANUFACTURE

(76) Inventors: Badr Omrane, Vancouver (CA); Clinton K. Landrock, North Vancouver (CA); Bozena Kaminska, Vancouver (CA); Yindar Chuo, Burnaby (CA)

(21) Appl. No.: 12/954,614

(22) Filed: Nov. 25, 2010

Related U.S. Application Data
(63) Continuation-in-part of application No. 12/628,106, filed on Nov. 30, 2009.
Application No. 12/628,106 is a continuation-in-part of application No. 12/386,789, filed on Apr. 22, 2009.

(51) Int. Cl. H01L 51/30

(52) U.S. Cl. 257/40; 438/46; 257/E51.024

(57) ABSTRACT

An organic electronic device (e.g. OLED, OPV, OES, OTFT) is disclosed. The organic electronic device includes a carrier substrate, a first electrode layer disposed on the carrier substrate, an organic active electronic region disposed on the first electrode layer, and an indium second electrode layer disposed and formed on the organic active electronic region by applying heat on an indium solid at a temperature between the melting temperature of indium and a threshold operating temperature of the organic layers to melt the indium solid on the organic active electronic region. The organic active electronic region includes one or more organic layers. A method of manufacturing an organic electronic device is also disclosed.

### 1. TECHNICAL FIELD

The present invention relates generally to organic electronic devices, and more particularly, to organic electronic devices with improved protection to their organic layers and methods of their manufacture.

### 2. BACKGROUND OF THE INVENTION

Organic electronic devices (OEDs) are devices that include layers of organic (and inorganic) materials, at least one of which can conduct an electric current. Illustrative examples of known OED constructions include organic photovoltaic devices (OPVs), organic light emitting diodes (OLEDs), and organic thin-film transistors (OTFT).

It is well known that essentially all organic materials may be adversely affected by oxygen and moisture. O₂ and moisture absorption is therefore a considerable challenge to the efficient manufacture of OEDs, such as OLEDs and OPVs. It is important, therefore, to protect these organic materials in OED layers from exposure to the open air. Some methods of making OEDs such as OLEDs and OPVs partially protect these organic material layers, for example, by performing a separate encapsulation step such as bonding a metal cap on top of an OED, hermetically sealing the entire OED, or manufacturing the OED in a vacuum, nitrogen or other inert environment. Separate encapsulation and fabrication steps in an inert environment typically add to manufacturing costs and complexity and do not provide a satisfactory solution for practical applications in electronic devices, which often require a device shelf-life that lasts more than a few days, exceeding the typical device lifetime of an OED such as an OPV fabricated using the current techniques. Device lifetimes of such conventionally manufactured OEDs can be as little as a couple of hours and typically no more than a few weeks even if stored in an inert environment such as nitrogen.

### 3. SUMMARY OF THE INVENTION

Certain features, aspects and examples disclosed herein are directed to an organic electronic device which may be adapted for a wide variety of constructions including organic photovoltaic devices (OPVs), organic light emitting diodes (OLEDs), organic thin-film transistors (OTFT), and polymer-based energy storage devices (capacitors, batteries, etc. which may comprise organic and/or inorganic electronic materials), for example. Certain features, aspects and examples are directed to a method of manufacturing an organic electronic device. Additional features, aspects and examples are discussed in more detail herein.

In accordance with a first aspect, an organic electronic device is disclosed. The organic electronic device includes a carrier substrate; a first electrode layer disposed on the carrier substrate; an organic active electronic region disposed on the first electrode layer, the organic active electronic region including one or more organic layers; and an indium second electrode layer disposed on the organic active electronic region by applying heat on an indium solid at a temperature between a melting temperature of indium and a threshold operating temperature of the organic layers to substantially melt the indium solid on at least a portion of the organic active electronic region, thereby forming the indium second electrode layer.

Embodiments of the organic electronic device of the present invention may include one or more of the following features. In some embodiments, the indium second electrode layer has a thickness greater than about 1 micrometer (μm). In certain other embodiments, the first electrode layer has a thickness between about 80 nanometers (nm) and 200 nanometers (nm).

According to some embodiments, the organic electronic device may comprise an exemplary organic photovoltaic device. The organic active electronic region in such embodiments may include a photoactive layer disposed on the first electrode layer. In other embodiments, the organic active electronic region further includes a hole transport layer disposed between the first electrode layer and the photoactive layer.

In certain embodiments, the photoactive layer has a thickness of up to about 200 nanometers (nm). In some embodiments, the hole transport layer has a thickness of up to about 160 nanometers (nm).

In accordance with an additional aspect of the present invention, a method of manufacturing an organic electronic device is disclosed. The method includes forming an first electrode layer on at least a portion of a carrier substrate; forming an organic active electronic region on at least a portion of the first electrode layer, the organic active electronic region including one or more organic layers; and

applying heat on an indium solid at a temperature between the melting temperature of indium and a threshold operating temperature of the organic layers to substantially melt the indium solid on the organic active electronic region, thereby forming an indium second electrode layer on the organic active electronic region.

Embodiments of the method of manufacturing an organic electronic device of the present invention may include one or more of the following features. In some embodiments, the indium second electrode layer has a thickness greater than about 1 micrometer (μm). In certain other embodiments, the first electrode layer has a thickness between about 80 nanometers (nm) and 200 nanometers (nm).

In some embodiments, the organic active electronic region includes a photoactive layer. In such embodiments, the step of forming an organic active electronic region on the first electrode layer includes forming the photoactive layer on the first electrode layer. In other embodiments, the organic active electronic region includes a hole transport layer in addition to a photoactive layer. The step of forming an organic active electronic region on the first electrode layer includes forming the hole transport layer on the first electrode layer, and forming the photoactive layer on the hole transport layer.

According to some embodiments, the photoactive layer is formed on the first electrode layer (or formed on the hole transport layer) by one or more of: spin coating; evaporation; brush painting; molding; printing; and spraying, to apply an organic photoactive material on the first electrode layer (or on the hole transport layer). Similarly, in some embodiments, the hole transport layer is formed on the first electrode layer by one or more of: spin coating; evaporation; brush painting; molding; printing; and spraying, to apply the first electrode layer.

Further advantages of the invention will become apparent when considering the drawings in conjunction with the detailed description.

### 4. BRIEF DESCRIPTION OF THE DRAWINGS

The organic electronic device and a method of manufacture of the present invention will now be described with reference to the accompanying drawing figures, in which:

FIG. 1A illustrates a cross-sectional view of an organic electronic device (“OED”) 100 according to an exemplary embodiment of the invention.

FIG. 1B illustrates a cross-sectional view of an OED having the construction of an OPV device 101 according to an embodiment of the invention.

FIG. 1C illustrates a cross-sectional view of an OED having the construction of an OLED 102 according to an embodiment of the invention.

FIG. 1D illustrates a cross-sectional view of an OED having the construction of an OTFT 103 according to an embodiment of the invention.

FIG. 2A illustrates a flow diagram of a method 200 of manufacturing an OED according to an exemplary embodiment of the invention.

FIG. 2B illustrates a flow diagram of a method 201 of manufacturing an OED according to another exemplary embodiment of the invention.

Similar reference numerals refer to corresponding parts throughout the several views of the drawings.

### 5. DETAILED DESCRIPTION OF THE INVENTION

In the present invention, a cap or top layer of indium (In) metal is optimally heat pressed on the active layers of the OED such as by heating the indium metal and applying under pressure on top of the active layers of the OED. The addition of a top indium layer obviates the need for vacuum or inert (such as nitrogen) environment manufacturing and the need for lamination or sealing of the OED active layers, as the heat pressed indium metal layer substantially draws or interacts with at least a portion of the oxygen (O₂) and moisture which may be typically comprised in the active material layer(s) of the OED. Accordingly, the application of a heat pressed indium metal layer allows the OED manufacturing process to be desirably performed in an ambient air environment.

Organic Electronic Device (“OED”)

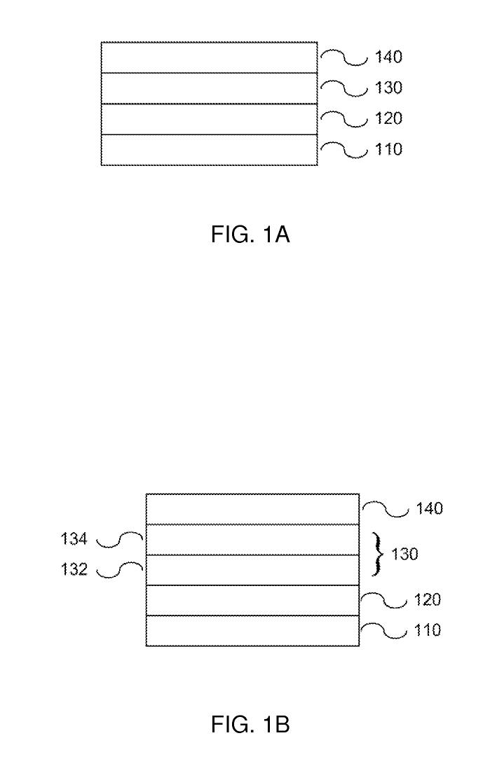

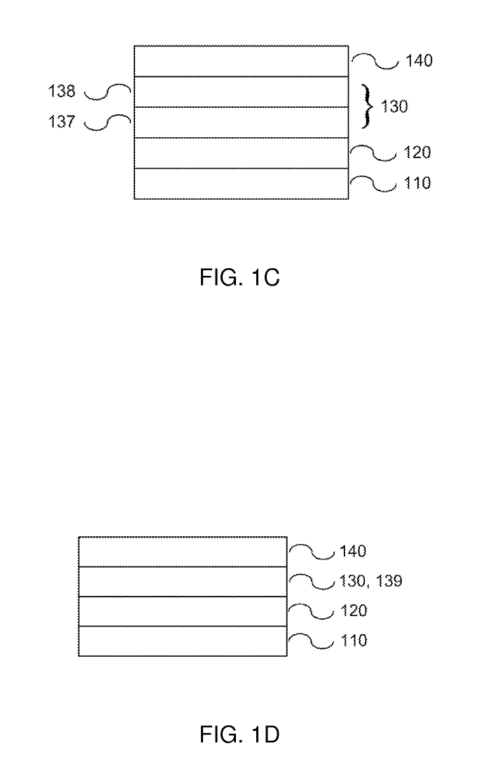

FIG. 1A illustrates a cross-sectional view of an OED 100 according to an exemplary embodiment of the invention. As shown in FIG. 1, the OED 100 includes a carrier substrate 110, a first electrode layer 120 disposed on carrier substrate 110, an organic active electronic region 130 disposed on at least a portion of first electrode layer 120, and a heat pressed indium second electrode layer 140 disposed and formed on organic active electronic region 130.

In a preferred embodiment, the indium second electrode layer 140 functions as the cathode and the first electrode layer 120 functions as the anode. In a preferred embodiment in which the first electrode layer 120 functions as the anode, the materials for forming the first electrode layer 120 preferably include one or more of: indium tin oxide (“ITO”), poly(3,4-ethylenedioxythiophene):poly(styrenesulfonate) (“PEDOT:PSS”), or a combination of both (ITO/PEDOT:PSS). Other materials suitable for forming the first electrode layer 120 may also be selected, as discussed in further detail herein.

The organic active electronic region 130 includes one or more organic layers. As used herein, a “layer” of a given material includes a region of that material the thickness of which is smaller than either of its length or width. Examples of layers may include sheets, foils, films, laminations, coatings, blends of organic polymers, metal plating, and adhesion layer(s), for example. Further, a “layer” as used herein need not be planar, but may alternatively be folded, bent or otherwise contoured in at least one direction, for example. The specific materials selected to form the organic layers of the organic active electronic region 130 depend on the particular construction of the OED 100, and are further discussed below in reference to FIGS. 1B-1D corresponding to several exemplary embodiments of the present invention. Illustrative examples of potential constructions of the OED 100 include organic photovoltaic devices (“OPVs”), organic light emitting diodes (“OLEDs”), organic thin-film transistors (“OTFTs”), organic rectifiers, and organic energy storage (“OES”) devices, for example.

According to an embodiment of the invention, the indium second electrode layer 140 may be formed on the organic active electronic region 130 by applying heat and/or pressure on an indium solid (such as indium metal foil, for example) at a temperature equal or greater than the melting temperature of indium, which is about 157° C., but less than a threshold operating temperature of the particular organic layers of organic active electronic region 130, and at a uniform, predefined pressure in order to melt the indium solid onto the organic active electronic region 130, thereby forming the indium second electrode layer 140. In one embodiment, the predefined pressure may range from ambient pressure to several kilopascals of compressive pressure, for example.

As used herein, the “threshold operating temperature of the organic layers” is the temperature at which one or more of the particular organic layers of the organic active electronic region 130 begin to thermally fail and/or degrade due to high heat, which would result in OED failure and/or degradation during or following fabrication. In an embodiment in which the OED is an organic photovoltaic device, for example, the threshold operating temperature of the organic layers is typically about 180° C.

In one aspect of the present invention, indium may be melted onto the organic layers of the organic active electronic region 130 (to form the second electrode layer 140 of the OED 100), thereby effectively reducing the adverse impact of at least one of moisture and oxygen contaminants on the OED 100. It is well known in the OED art that the organic materials used in making the OED can be adversely affected by heat, light, oxygen, and moisture, and that the common low work function cathode electrode materials (e.g. calcium/aluminum (Ca/Al), aluminum (Al), lithium fluoride (LiF), and aluminum oxide/aluminum (Al₂O₃/Al)) used in cathode electrodes in typical OEDs (e.g. OLEDs and OPVs) are also sensitive to oxygen and moisture, which can cause corrosion and degradation of the cathode. The present invention reduces the adverse effects of oxygen and/or moisture contamination on the OED 100, in particular, an OPV, by melting indium onto the organic layers of the OED or pressing indium directly onto a “wet” organic layer of the OED. OEDs with such indium cathode electrodes according to an embodiment of the present invention may desirably display advantages in function compared to a conventional OED that employs a conventional aluminum (Al) cathode, as the indium cathode OEDs constructed using the present method result in a significantly longer device operational lifetime, as discussed in greater detail below.

Having generally described the components of the OED 100 according to an embodiment of the invention, the specific features of these components are now described in greater detail in reference to the particular construction of the OED 100.

Organic Photovoltaic (“OPV”) Device

FIG. 1B illustrates a cross-sectional view of an OED having the construction of an OPV device 101 (hereinafter “OPV 101”) according to an embodiment of the invention. As shown in FIG. 1B, in the embodiment in which the OED is an OPV 101, the organic active electronic region 130 includes one or more organic layers. Specifically, in one embodiment, the organic active electronic region 130 includes a photoactive layer 134 disposed directly on the first electrode layer 120. The photoactive layer 134 is comprised of organic photoactive materials that in response to the absorption of light, convert light energy to electrical energy.

In an optional embodiment, the organic active electronic region 130 may further include a hole transport layer 132 disposed between the first electrode layer 120 and the photoactive layer 134, as shown in FIG. 1B. The hole transport layer 132 is comprised of organic hole transport material that facilitates the transport of electron holes from the photoactive layer 134 to the first electrode layer 120. In the embodiment of the OPV 101 as shown in FIG. 1B, the first electrode layer 120 functions as the anode, and the indium second electrode layer 140 functions as the cathode.

In a preferred embodiment, the OPV 101 is a bulk heterojunction OPV, and exemplary organic photoactive materials of the photoactive layer 134 may include a photoactive electron donor-acceptor blend such as poly(3-hexylthiophene):[6,6]-phenyl-C₆₁-butyric acid methyl ester (P3HT:PCBM), for example. Exemplary hole transport materials for the hole collector layer 132 may include conductive polymers, such as

PEDOT:PSS, for example.

The carrier substrate 110 of the OPV 101 may comprise any suitable material that can support the organic layers 132 and 134, and the electrode layers 120 and 140 disposed thereon. Suitable exemplary materials for the carrier substrate 110 may include plastic and glass, for example.

Preferably, the first electrode (anode) layer 120 is substantially transparent in order to permit light to enter from the underside or bottom of the OPV 101. Suitable exemplary substantially transparent first electrode (anode) layer 120 for the OPV 101 includes one or more light transmissive metal oxides such as indium tin oxide (“ITO”), zinc tin oxide, as well as other substantially transparent anode materials known in the art, such as PEDOT:PSS. In alternative embodiments, first electrode (anode) layer 120 may include a substantially opaque anode material such as silver or gold with nanohole arrays (“NHA”) formed therein using known milling techniques (e.g. focused ion beam (“FIB”) milling), lithography techniques (e.g. nano-imprint lithography, deep UV lithography, and electron beam lithography), hot stamping, and embossing, for example, to desirably controllably provide for transmission of light energy to the active layer(s).

In one embodiment where the OED is an OPV (e.g. OPV 101), the indium second electrode (cathode) layer 140 may desirably have a thickness greater than about 1 micrometer (μm); the first electrode (anode) layer 110 may desirably have a thickness between about 80 nanometers (nm) and 200 nanometers (nm); the photoactive layer 134 may desirably have a thickness up to about 200 nanometers (nm), and the hole transport layer 132 may desirably have a thickness up to about 160 nanometers (nm).

In a preferred embodiment where the OED is an OPV, the second indium electrode (cathode) layer 140 has a thickness between about 25 micrometers (μm) and 100 micrometers (μm); the first electrode (anode) layer 110 has a thickness of about 100 nanometers (nm); the photoactive layer 134 has a thickness between about 40 nanometers (nm) to 100 nanometers (nm), and the hole collector layer 132 has a thickness between about 40 nanometers (nm) and 100 nanometers (nm).

Organic Light Emitting Diode (“OLED”)

FIG. 1C illustrates a cross-sectional view of an OED having the construction of an OLED 102, according to an embodiment of the invention. In one embodiment, such as shown in FIG. 1C, the first electrode layer 120 functions as the anode, and the indium second electrode layer 140 functions as a cathode.

As shown in FIG. 1C, in an embodiment in which the OED is an OLED 102, the organic active electronic region 130 may comprise one or more organic layers (and optionally also one or more inorganic layers). In one embodiment, the organic active electronic region 130 may include an emissive layer 138 disposed on at least a portion of the first electrode (anode) layer 120.

In another embodiment, the organic active electronic region 130 may further include a hole transport layer. For example, in the embodiment as shown in FIG. 1C, the organic active electronic region 130 further includes a hole transport layer 137 disposed between the first electrode (anode) layer 120 and the emissive layer 138. The hole transport layer 138 may advantageously be provided to assist in the transfer of positive charges or “holes” from the first electrode (anode) layer 120 to the emissive layer 138, for example. In other embodiments, the organic active electronic region 130 may include additional organic layers (not shown) advantageously provided to assist in the transfer of electrons from the indium second electrode layer 140 to the emissive layer 138, for example.

The carrier substrate 110 of the OLED 102 may comprise any suitable material that can support the active electronic layers (such as organic layers 135-138), and the electrode layers 120 and 140 disposed thereon. Suitable exemplary materials for the carrier substrate 110 may include plastic and glass, for example.

In a preferred embodiment, OLED 102 may be arranged in a bottom emissive configuration operable to provide photon emission through the bottom surface of the OLED 120. In such a preferred embodiment, the first electrode (anode) layer 120 is at least substantially transparent. Suitable exemplary substantially transparent first electrode (anode) layer materials 120 for the OLED 102 may include one or more light transmissive metal oxides such as indium tin oxide (“ITO”), zinc tin oxide, as well as other substantially transparent anode materials known in the art.

Organic Thin-Film Transistor (“OTFT”)

FIG. 1D illustrates a cross-sectional view of an OED having the construction of an OTFT 103 according to an embodiment of the invention. As shown in FIG. 1D, in one embodiment in which the OED is an OTFT 103, the organic active electronic region 130 includes an organic semiconductor layer 139. In one embodiment, the organic semiconductor layer 139 may comprise polymeric and/or oligomeric materials, such as polythiophene, poly(3-alkyl)thiophene, polythienylenevinylene, poly(para-phenylenevinylene), or polyfluorenes or their families, copolymers, derivatives, or mixtures thereof, for example.

In one embodiment of the OTFT (e.g. OTFT 103), the first electrode layer 120 may be used to form, for example, the gate contact of the OTFT 103. The indium second electrode layer 140 may be used to form, for example, the source and drain contacts of the OTFT 103. In an alternative embodiment, the first electrode layer 120 may be used to form the source and drain contacts of the OTFT 103 while the indium second electrode layer 140 may be used to form the gate contact of the OTFT 103.

The carrier substrate 110 of the OTFT 103 may comprise any suitable material that can support the active electronic layer(s), such as organic semiconductor layer 139, and the electrode layers 120 and 140 disposed thereon. Suitable exemplary materials for the carrier substrate 110 may include plastic and glass, for example.

Organic Energy Storage (“OES”) Device

In an alternative embodiment of the present invention, an OED may comprise an organic energy storage (OES) device construction, which may typically comprise an anode layer, a cathode layer, and an energy-storing polymer layer situated between the anode and cathode layers. In one embodiment, the energy storage polymer may comprise an ionic polymer material, such as a fluoropolymer-based ionic polymer material, for example. One exemplary such ionic polymer material may comprise a perfluorosulfonic acid (PFSA)/polytetrafluoroethylene (PTFE) copolymer ionic polymer, such as is commercially available as Nafion™ N-115 ionic polymer from the E.I. DuPont et Nemours Company, for example. In one embodiment of such an OES device construction, the ionic polymer material between the anode and cathode layers may comprise a non-hydrated PFSA/PTFE ionic polymer material such as non-hydrated Nafion™ N-115 which may further optionally be doped with one or more cations such as for example, Li+ and/or Na+ ions, such as to improve energy storage capacity. In another embodiment, an OES device may additionally comprise one or more optional inorganic active layers, such as an inorganic dielectric layer for example.

In one exemplary embodiment of an OES device according to the present invention, anode and cathode elements may comprise conductive film electrodes comprising indium metal (such as indium metal foil) layers which are heat pressed onto opposite major surfaces of a thin ionic polymer layer located between the conductive film electrodes. In another embodiment, a suitable ionic polymer material may be applied or deposited (such as by spin-coating, printing, spraying or spreading, for example) onto a surface of at least one of the conductive film electrodes, such as the anode. In such an embodiment, the cathode may comprise a conductive film electrode such as an indium metal film (such as indium metal foil, for example), which is heat pressed onto the ionic polymer film layer.

In a further alternative embodiment of the present invention, an organic energy storage (OES) device may comprise anode and cathode conductive film electrodes with an ionic polymer film situated therebetween, where one or both of the anode and cathode conductive film electrodes comprises more than one electrode material. In one such embodiment, the conductive film anode may comprise two layers of different conductive materials, such as a first layer of a first metallic material situated directly in contact with a first major surface of the ionic polymer material, and a second layer of a second metallic electrode material applied and/or adhered to the first metallic material, such as to improve electrical contact between the ionic polymer and the second layer of electrode material. In such an embodiment, the cathode conductive film electrode may comprise an indium metal film which may be heat pressed onto a second major surface of the ionic polymer material film, for example. Further optional embodiments of ionic polymer metal composite organic energy storage (OES) device constructions which may optionally comprise at least one heat pressed indium metal electrode layer according to the present invention are disclosed in previously filed U.S. patent application Ser. No. 12/628,106, the contents of which are hereby incorporated by reference in their entirety.

Method of Manufacturing an OED

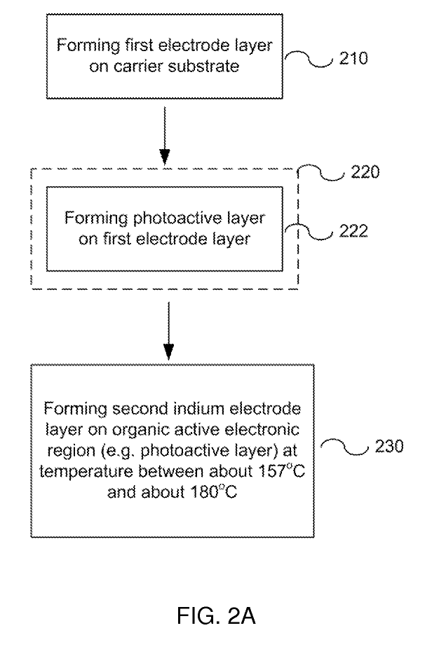

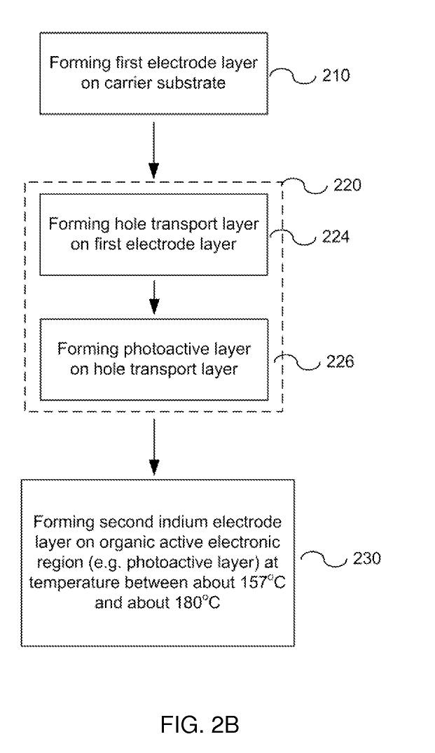

FIG. 2A illustrates a flow diagram of a method 200 of manufacturing an OED according to an exemplary embodiment of the invention. The method 200 according to this exemplary embodiment may be adapted to manufacture the OED 100 as shown in FIG. 1A, and may be particularly adapted to manufacture any one type of OED, such as an OPV (e.g. OPV 101 shown in FIG. 1B), an OLED (e.g. OLED 103 shown in FIG. 1C), an OTFT (e.g. OTFT 103 shown in FIG. 1C), or an OES device, for example. The method 200 in this exemplary embodiment begins with forming a first electrode layer 120 on a carrier substrate 110, as shown at operation 210. In one such embodiment, the substrate 110 may be in the form of a sheet or continuous film. The continuous film can be used, for example, for providing roll-to-roll continuous manufacturing processes according to the present invention, as may be particularly desirable for use in a high-volume manufacturing environment.

The first electrode layer 120 may be formed on the carrier substrate 110 by any suitable means or method so as to deposit, attach, adhere or otherwise suitably join the first electrode layer 120 to at least a portion of the top surface of the carrier substrate 110. In one embodiment, the first electrode layer 120 may be formed on the carrier substrate 110 by any suitable deposition techniques, including physical vapor deposition, chemical vapor deposition, epitaxy, etching, sputtering and/or other techniques known in the art and combinations thereof, for example. In some embodiments, the method 200 may additionally include a baking or annealing step, which may optionally be conducted in a controlled atmosphere, such as to optimize the conductivity and/or optical transmission characteristics of the first electrode layer 120, for example.

If the fabrication of an OPV (e.g. OPV 101 shown in FIG. 1B) is desired, in one embodiment, the first electrode layer 120 functions as the anode. Typical anode materials for an OPV 101 are listed above in the section for the “first electrode (anode) layer 120” with reference to FIG. 1B.

Next, the method 200 proceeds to forming an organic active electronic region 130 on the first electrode layer 120, as shown at operation 220. The organic active electronic region 130 includes one or more organic layers. In one embodiment in which the method 200 is particularly adapted to manufacture an OPV (e.g. OPV 101), the organic active electronic region 130 includes a photoactive layer 134. The operation 220 of forming an organic active electronic region 130 on the first electrode layer 120 includes forming the photoactive layer 134 on the first electrode layer 120, as shown at operation 222.

The photoactive layer 134 may be formed on the first electrode layer 120 at operation 222 by any suitable organic film deposition techniques, including, but not limited to, spin coating, spraying, printing, brush painting, molding, and/or evaporating on a photoactive material on the first electrode layer 120 to form photoactive layer 134, for example. Exemplary suitable organic photoactive materials are listed above in the section for the “photoactive layer 134” with reference to FIG. 1B.

Following the formation of the organic active electronic region 130 on the first electrode layer 120 at operation 222, the method 200 proceeds to operation 230 at which an indium second electrode layer 140 is formed on the organic active electronic region 130. The indium second electrode layer 140 may be formed on the organic active electronic region 130 (i.e. the photoactive layer 134) by applying heat on an indium metal solid (e.g. indium metal foil) such as at a temperature between the melting temperature of indium, which is about 157° C., and a threshold operating temperature of one or more of the organic layers of the organic active electronic region 130, at a uniform, predefined pressure. In an embodiment in which the OED is an organic photovoltaic device, for example, the threshold operating temperature of the organic layers may be about 180° C.

The heat applied on the indium solid (e.g. foil) causes the indium to melt onto the organic active electronic region 130, and in the particular embodiment as shown in FIG. 1B, to melt onto the photoactive layer 134. The melted indium is then allowed to cool, resulting in the formation of the indium second electrode layer 140 on the photoactive layer 134.

In a particular embodiment of the method 200 in the manufacturing of an OPV 101, the indium second electrode layer 140 may be formed on the organic active electronic region 130 by heating and pressing on an indium foil layer onto the photoactive layer 134, such as by using a heat press. In another embodiment directed to substantially continuous manufacturing environments, the indium second electrode layer 140 may be formed on the organic active electronic region 130 by heating and pressing an indium metal foil layer onto the photoactive layer 134 using a heated rolling press, or heated rollers, for example.

FIG. 2B illustrates a flow diagram of a method 201 of manufacturing an OED according to another exemplary embodiment of the invention. In an embodiment in which the method 201 is particularly adapted to manufacture an OPV (e.g. OPV 101 shown in FIG. 1B), the organic active electronic region 130 may optionally include a hole transport layer 132 in addition to the photoactive layer 134. In such an embodiment, the operation 220 of forming an organic active electronic region 130 on the first electrode layer 120 as shown in the method 201 of FIG. 2B, as compared to the method 200 embodiment shown in FIG. 2A, alternatively includes forming the hole transport layer 132 on the first electrode layer 120, as shown at operation 224, followed by forming the photoactive layer 134 on the hole transport layer 132, as shown at operation 226.

The hole transport layer 132 may be formed on the first electrode layer 120 at operation 224 by any suitable organic film deposition techniques, including, but not limited to spin coating, evaporation, brush painting, printing, molding, and spraying on a hole transport material on the first electrode layer 120. Exemplary suitable hole transport materials are listed above in the section for the “hole transport layer 132” with reference to FIG. 1B. Similarly, the photoactive layer 134 may be formed on the hole transport layer 132 at operation 226 by any suitable organic film deposition techniques as described.

Still referring to FIG. 2B, following the formation of the organic active electronic region 130 on the first electrode layer 120 at operation 226, the method 201 proceeds to operation 230 at which an indium second electrode layer 140 is formed on the organic active electronic region 130, substantially similar to that described in connection with the method 200 embodiment shown in FIG. 2B, and the description of operation 230 is therefore omitted for brevity.

Additionally, in other optional embodiments, other steps (not shown) such as washing, cleaning and neutralization of films and/or layers, the addition of insulation layers (e.g. oxide and/or dielectric layers), masks and photo-resists may be added into the workflow of the methods 200 and 201 of manufacturing OEDs according to the present invention. These steps are not specifically enumerated above for clarity, however they may be applied in embodiments of the invention according to their requirement and/or suitability such as before and/or after the steps specifically enumerated in the embodiments above, as may be necessary and/or desirable such as for pre- and/or post-treatment of thin film layers of the OEDs as described in the manufacturing method embodiments above. Other additional and optional steps (not shown) like adding lead wires to connect the anode and cathode layers to an external load or power source, packaging/encapsulation, and re-sizing of the OEDs to meet desired specifications may also be included in the workflow. For example, in some embodiments, the methods 200 and 201 may further include an optional encapsulating step to encapsulate, such as by hermetically sealing, the OED (e.g. OPV 101) to further insulate the OED from outside ambient environmental conditions, such as small molecule contaminants, air and moisture, for example that may adversely impact the organic materials used in the OED and by extension may affect the operational lifetime of the OED.

Test Results

Tables 1 and 2 below illustrate test results comparing an OPV fabricated according to a method of manufacturing an OED having a configuration of ITO/PEDOT:PSS/P3HT:PCBM/In utilizing an indium metal cathode (“indium-OPV”) according to an embodiment of the invention with an conventional OPV having a conventional configuration of ITO/PEDOT:PSS/P3HT:PCBM/Al utilizing a conventional aluminum cathode (“aluminum-OPV). Except for the aluminum deposition step by physical vapour deposition (PVD) in connection with aluminum-OPV fabrication, neither the indium-OPV nor the aluminum-OPV under test was fabricated in a vacuum condition, and neither of the tested OPV constructions were manufactured using a method which included an encapsulation step to hermetically seal the OPV. Further, neither the indium-OPV nor the aluminum-OPV was laminated during or following manufacture.

As shown in Table 1, test results indicate that an indium-OPV had the following initial device operation characteristics: open circuit voltage (V_{oc}) of about 0.395V and short circuit current (I_{sc}) of about 4.22 mA/cm². Following sixty-eight (68) days of operation after the date of device fabrication, the indium-OPV had the following device operation characteristics: V_{oc} of about 0.370V, or about 94% of the initial operating open circuit voltage capacity immediately following manufacture, and I_{sc} of about 3.43 mA/cm², or about 81% of the initial operating short circuit current capacity immediately following manufacture.

TABLE 1
Indium-OPV

| | Open Circuit | Short Circuit |
|---|---|---|
| Time | Voltage (V_{oc}) | Current (I_{sc}) |
| Initial | 0.395 V | 4.22 mA/cm² |
| After 68 days | 0.370 V | 3.43 mA/cm² |

As shown in Table 2, the test results indicate that, as compared to an indium-OPV, a conventional aluminum-OPV exhibits significant device degradation shortly after twenty-four (24) hours from fabrication. That is, the aluminum-OPV has the following initial device operation characteristics: V_{oc} of about 0.590V and I_{sc} of 6.00 mA/cm². After about twenty-four (24) hours following fabrication, the conventional aluminum-OPV already exhibits significant device degradation, as indicated by the following device operation characteristics: V_{oc} of about 0.020V, or about 3.4% of the initial open circuit voltage capacity immediately following manufacture, and I_{sc} of about 0.08 mA/cm², or about 1.3% of the initial short circuit current capacity immediately following manufacture.

TABLE 2
Aluminum-OPV

| | Open Circuit | Short Circuit |
|---|---|---|
| Time | Voltage (V_{oc}) | Current (I_{sc}) |
| Initial | 0.590 V | 6.00 mA/cm² |
| After 24 hours | 0.020 V | 0.08 mA/cm² |

Accordingly, experimental results indicate that an OED, in particular, an OPV, having a cathode electrode fabricated according to an embodiment of the present invention by melting indium solid (e.g. indium metal foil), such as with a heat press, onto the organic layers of the OED, demonstrated a significantly longer device operational lifetime when compared to a conventional OED that employs an aluminum cathode. Accordingly such an OED comprising a heat pressed indium cathode according to an embodiment of the invention and manufactured using a manufacturing method according to an embodiment of the present invention may desirably provide improved operating characteristics, particularly over extended periods of operation, such as may be desirable for real world, practical applications of such OEDs in electronic devices which may be typically expected to have a shelf life and useful operational life of more than a few days.

The OEDs and the methods of manufacture described above according to embodiments of the present invention may additionally include one or more of the following advantages. Embodiments of the invention may desirably reduce manufacturing complexity and costs associated with conventional OED fabrication. As discussed, a conventional OED, particularly a conventional OPV, typically employs aluminum as the cathode layer, which is typically deposited on the organic layers using thermal physical vapour deposition (PVD) techniques. This typically costly thermal PVD process is eliminated from the workflow of the present invention, as the indium second electrode layer 140, which may function as the cathode, is alternatively deposited on the organic layers by melting indium solid (e.g. indium metal foil) directly onto the active organic electronic region of the OED, thereby effectively eliminating the relatively complex and costly conventional cathode deposition processes.

The exemplary embodiments herein described are not intended to be exhaustive or to limit the scope of the invention to the precise forms disclosed. They are chosen and described to explain the principles of the invention and its application and practical use to allow others skilled in the art to comprehend its teachings.

As will be apparent to those skilled in the art in light of the foregoing disclosure, many alterations and modifications are possible in the practice of this invention without departing from the spirit or scope thereof. Accordingly, the scope of the invention is to be construed in accordance with the substance defined by the following claims.

What is claimed is:

1. An organic electronic device, comprising:
a carrier substrate;
a first electrode layer disposed on the carrier substrate;
an organic active electronic region disposed on said first electrode layer, said organic active electronic region comprising one or more organic layers; and
an indium second electrode layer disposed on said organic active electronic region by applying heat on an indium solid at a temperature between a melting temperature of indium and a threshold operating temperature of at least one of said organic layers to substantially melt said indium solid onto the organic active electronic region, thereby forming said indium second electrode layer.

2. The organic electronic device according to claim 1, wherein said indium second electrode layer has a thickness greater than 1 micrometer (μm).

3. The organic electronic device according to claim 1, wherein said first electrode layer has a thickness between 80 nanometers (nm) and 200 nanometers (nm).

4. The organic electronic device according to claim 1 wherein said organic electronic device comprises at least one of:
an organic photovoltaic device, wherein said organic active electronic region comprises a photoactive layer disposed on said first electrode layer;
an organic light emitting diode device, wherein said organic active electronic region comprises an emissive layer disposed on said first electrode layer;
an organic thin film transistor device, wherein said organic active electronic region comprises an organic semiconductor layer disposed on said first electrode layer; and
an organic energy storage device, wherein said organic active electronic region comprises an energy storing polymer layer disposed on said first electrode layer.

5. The organic electronic device according to claim 1, wherein said organic electronic device comprises an organic photovoltaic device, and wherein said organic active electronic region comprises a photoactive layer, and a hole transport layer disposed between said first electrode layer and said photoactive layer.

6. The organic electronic device according to claim 1, wherein said organic electronic device comprises an organic light emitting diode device, and wherein said organic electronic region comprises an emissive layer and a hole transport layer disposed between said first electrode layer and said emissive layer.

7. The organic electronic device according to claim 1, wherein said organic electronic device comprises an organic energy storage device, and wherein said organic energy storage device comprises an ionic polymer layer disposed on said first electrode layer.

8. A method of manufacturing an organic electronic device, comprising:
forming an first electrode layer on a carrier substrate;
forming an organic active electronic region on said first electrode layer, said organic active electronic region comprising one or more organic layers; and
applying heat on an indium solid at a temperature between the melting temperature of indium and a threshold operating temperature of at least one of said organic layers to substantially melt the indium solid on the organic active electronic region, thereby forming an indium second electrode layer on said organic active electronic region.

9. The method according to claim 8, wherein said indium second electrode layer has a thickness greater than 1 micrometer (μm).

10. The method according to claim 8, wherein said first electrode layer has a thickness between 80 nanometers (nm) and 200 nanometers (nm).

11. The method according to claim 8, wherein said organic active electronic region comprises a photoactive layer, the step of forming an organic active electronic region on said first electrode layer comprising:
forming said photoactive layer on said first electrode layer.

12. The method according to claim 8, wherein said organic active electronic region comprises a photoactive layer and a hole transport layer, the step of forming an organic active electronic region on said first electrode layer comprising:
forming said hole transport layer on said first electrode layer; and
forming said photoactive layer on said hole transport layer.

13. The method according to claim 8, wherein said organic active electronic region comprises an emissive layer, the step of forming an organic active electronic region on said first electrode layer comprising:
forming said emissive layer on said first electrode layer.

14. The method according to claim 13, wherein said organic active electronic region comprises an emissive layer and a hole transport layer, the step of forming an organic active electronic region on said first electrode layer comprising:
forming said hole transport layer on said first electrode layer; and
forming said emissive layer on said hole transport layer.

15. The method according to claim 8, wherein said organic active electronic region comprises an ionic polymer energy storage layer, the step of forming an organic active electronic region on said first electrode layer comprising:
forming said ionic polymer energy storage layer on said first electrode layer.

16. The method according to claim 11, wherein said photoactive layer is formed on said first electrode layer by at least one of: spin coating; evaporating; printing; brush painting; molding; and spraying, an organic photoactive material onto said first electrode layer.

17. The method according to claim 12, wherein said hole transport layer is formed on said first electrode layer by at least one of: spin coating; evaporating; printing; brush painting; molding; and spraying, an organic hole transport material onto said first electrode layer.

18. The method according to claim 12, wherein said photoactive layer is formed on said hole transport layer by at least one of: spin coating; evaporating; printing; brush painting; molding; printing; and spraying, an organic photoactive material onto said hole transport layer.

19. The method according to claim 13, wherein said emissive layer is formed on said first electrode layer by at least one of: spin coating; evaporating; printing; brush painting; molding; and spraying, an organic emissive material onto said first electrode layer.

20. The method according to claim 14, wherein said ionic polymer layer is formed on said first electrode layer by at least one of: spin coating; evaporating; printing; brush painting; molding; and spraying, an ionic polymer material onto said first electrode layer.
